(19) United States
(12) Patent Application Publication
(10) Pub. No.: US 2025/0046644 A1
(43) Pub. Date: Feb. 6, 2025

(54) WAFER TRANSFER PADDLES WITH MINIMUM CONTACT AREA STRUCTURES FOR REDUCED BACKSIDE MARKING

(71) Applicant: Lam Research Corporation, Fremont, CA (US)

(72) Inventors: Andrew Borth, Newberg, OR (US); Troy Gomm, Tigard, OR (US); Damien M. Slevin, Salem, OR (US); Todd Schroeder, Sherwood, OR (US)

(73) Assignee: Lam Research Corporation, Fremont, CA (US)

(21) Appl. No.: 18/718,751

(22) PCT Filed: Dec. 27, 2022
(86) PCT No.: PCT/US2022/082442

§ 371 Date: Jun. 11, 2024

Related U.S. Application Data
(60) Provisional application No. 63/266,929, filed on Jan. 19, 2022.

(51) Int. Cl. H01L 21/687; H01J 37/32; H01L 21/67

(52) U.S. Cl. CPC H01L 21/68707; H01J 37/32733; H01L 21/67017; H01J 2237/3321

(57) ABSTRACT

A wafer processing apparatus comprising a vacuum chamber, the vacuum chamber comprising a wafer transfer arm and a wafer transfer paddle coupled to the wafer transfer arm. The wafer transfer paddle comprises at least one minimum contact area (MCA) feature integral with an upper surface of the wafer transfer paddle and extending a z-height over the upper surface of the wafer transfer paddle. The wafer transfer paddle comprises a gas flow bypass structure on or adjacent to the MCA feature.

### CLAIM FOR PRIORITY

This application is a continuation of and claims the benefit of priority to U.S. Patent Application No. 63/266,929, filed Jan. 19, 2022, titled “WAFER TRANSFER PADDLES WITH MINIMUM CONTACT AREA STRUCTURES FOR REDUCED BACKSIDE MARKING,” and which is incorporated by reference in its entirety.

### BACKGROUND

Substrate processing tools are used to perform treatments such as deposition and etching of film on substrates like semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. The deposition may be performed in a wafer processing chamber such as a PECVD chamber comprising multiple stations for processing more than one wafer at a time. In some tools, a wafer transfer system may be included within the wafer processing chamber. A wafer transfer system may comprise a rotary indexer, for example. The rotary indexer may comprise arms having wafer transfer paddles. Wafers may be supported on the wafer transfer paddles during transfer to and from processing stations. The wafer transfer paddles may comprise minimum contact area (MCA) features such as mesa-like structures to provide minimal contact to the wafers. During deposition, the wafer transfer paddles may be moved to a neutral position to allow wafer to seat onto wafer chuck pedestals.

During deposition the wafer transfer paddles may be exposed to process gases. MCA features may receive a train of process gases containing deposition precursors. Films of deposited material frequently grow on the wafer contact surfaces of the MCA features. When contacted again to a wafer, the film deposited on the MCA feature may transfer to the wafer backside due to preferential adhesion.

the wafer substrate is clamped down on a substrate support (e.g., a pedestal). The pedestal may hold the substrate by electrostatic clamping or by vacuum clamping facilitated by a chuck on the pedestal. In either mode, the wafer substrate is pressed against the chuck. In many processes, the wafer is thermally cycled to control deposition or etching chemistry on the exposed surface of the wafer substrate. Microscopic irregularities on the chuck surface may rub or scrape off small particles from the backside of the wafer substrate during thermal equilibration as the wafer expands or contracts. The particles may accumulate on the chuck, and transfer to subsequent wafer substrates during sequential processing of multiple wafers in the same tool. The contamination of wafer backsides by adventitious particle attachment may affect downstream processing. For example, backside particle contamination may affect quality of subsequent photolithography operations.

A common solution is to incorporate minimum contact area (MCA) structures on the chuck surface to minimize contact between the backside of the wafer substrate and the chuck. MCA structures may be in the form of a small number of pillars, for example, distributed on the chuck surface upon which the wafer substrate may rest. The MCA structures may offset the wafer substrate from the chuck surface by one to 10 mils (e.g., approx. 25 to 250 microns). The MCA structures may be distributed in a pattern that leaves the wafer backside mostly undisturbed. The contact area of the MCA structures may be restricted to a small fraction of the wafer area. While minimal contact area may be beneficial to mitigate particle generation, clamping forces may be magnified over MCA structures, pressing the structures into the backside surface of the substrate. Often, the wafer backside may be coated with a resist layer or a deposited oxide or nitride film, for example. The wafer backside may comprise patterned metallization, insulator and semiconductor layers for contacts and integrated circuits. MCA structures, while beneficial for reducing contamination, may damage patterned layers or deposited films by piercing through resist layers or cracking dielectric films. A solution is needed for reducing damage caused by MCA structures while maintaining their benefits.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a plan view of a wafer processing chamber comprising a four-arm rotary indexer in a loading position, in accordance with at least one embodiment.

FIG. 1B illustrates a plan view of a wafer processing chamber comprising a four-arm rotary indexer in a neutral (parked) position, in accordance with at least one embodiment.

FIG. 2A a plan view of a first embodiment of a wafer transfer paddle comprising minimum contact area (MCA) features, in accordance with at least one embodiment.

FIG. 2B illustrates a cross-sectional view of the wafer transfer paddle shown in FIG. 2A, in accordance with at least one embodiment.

FIG. 3A illustrates a vertical cross-sectional view of an MCA feature, in accordance with at least one embodiment.

FIGS. 3B-3E illustrate plan views of MCA features having various horizontal cross-section geometries, in accordance with at least one embodiment.

FIG. 4 illustrates a plan view of a wafer transfer paddle comprising gas diverting features, in accordance with at least one embodiment.

FIG. 5 illustrates a plan view of view of a wafer transfer paddle comprising gas diverting features, in accordance with at least one embodiment.

FIGS. 6A and 6B illustrate a flow chart summarizing an exemplary method for using a wafer transfer paddle in accordance with at least one embodiment.

FIG. 7 illustrates a schematic profile view of a wafer processing system comprising at least one wafer transfer paddle, in accordance with at least one embodiment.

### DETAILED DESCRIPTION

Various embodiments describe minimum contact area stand-off patterns for reducing wafer backside damage. In the following description, numerous specific details are set forth, such as structural schemes, to provide a thorough understanding of embodiments of the present disclosure. It will be apparent to one skilled in the art that embodiments of the present disclosure may be practiced without these specific details. In other instances, well-known features, such as gas line tubing fittings, heating elements and snap switches, are described in lesser detail to not unnecessarily obscure embodiments of the present disclosure. Furthermore, it is to be understood that the various embodiments shown in the figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment,” “at least one embodiment,” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

Here, terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

Here, “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

Here, “adjacent” may generally refer to a position of a thing being next to (e.g., immediately next to or close to with one or more things between them) or adjoining another thing (e.g., abutting it).

Here, “wafer processing tool” may generally refer to an apparatus comprising a vacuum chamber equipped for performing processes employed in semiconductor microchip fabrication. For example, in at least one embodiment, a wafer processing tool may be employed in chemical and physical deposition processes, such as plasma-enhanced chemical vapor deposition (PECVD) or reactive ion etching (RIE).

Here, “vacuum chamber” may generally refer to a chamber that is operable to maintain a high vacuum (e.g., 20 torr or less). In at least one embodiment, a vacuum chamber may include devices and apparatuses for performing semiconductor device fabrication operations.

Here, “wafer transfer arm” may generally refer to a robotic arm that can be controlled remotely. In at least one embodiment, a wafer transfer arm may be employed to transfer wafers into and out of a vacuum chamber in a wafer processing tool.

Here, “wafer transfer paddle” may generally refer to a specialized end effector for holding a wafer while being transferred by a wafer transfer arm. In at least one embodiment a wafer transfer paddle may have a U-shape.

Here, “minimum contact area” may generally refer to a plurality of raised minimum contact area (MCA) structures, such as mesas or bumps on a wafer transfer paddle. In at least one embodiment, MCA structures are employed as stand-offs between a wafer and the wafer transfer paddle. The MCA structures may be distributed over a surface of a wafer transfer paddle such that the contact between the wafer and the wafer transfer paddle is as minimal as practical.

Here, “gas flow bypass structure” may generally refer to a specialized MCA structure comprising an opening through which process gases impinging on the wafer transfer paddle may pass to circumvent depositing films on the MCA structure. In at least one embodiment, a gas flow bypass structure includes sloped sidewalls and sharp edges to avoid film adherence.

Here, “edge” may generally refer to an edge of a wafer transfer paddle In at least one embodiment, an edge may be straight or curved.

Here, “notch” may generally refer to a cut or slot in the wafer transfer paddle extending to an edge of the wafer transfer paddle.

Here, “curved edge” may generally refer to an edge having a curvature.

Here, “peninsular structure” may generally refer to a thin region extending off of an edge or sidewall of a wafer transfer paddle.

Here, “sidewall” may, in at least one embodiment, generally refer to an edge of a wafer transfer paddle.

Here, “distal end” may generally refer to a far end of a peninsular structure. For example, it is the far end of a peninsular structure that extends furthest from the edge of the wafer transfer paddle.

Here, “lower surface” may generally refer to a surface of a wafer transfer paddle opposing the upper surface of the wafer transfer paddle. In at least one embodiment, the upper surface faces the wafer generally, and may comprise MCA structures.

Here, “annular form” may generally refer to a ring shape form of a MCA structure. For example, a gas flow bypass structure may have a generally annular form.

Here, “wafer contact surface” may generally refer to a a top surface of a MCA structure. In at least one embodiment, a wafer contact surface may be a rounded convex surface or a rim surrounding an opening extending through the MCA structure (e.g., a gas flow bypass structure).

Here, “rim” may generally refer to a boundary of an opening. In at least one embodiment, a rim of an opening may be a crest of a sidewall at boundary of an opening in a MCA structure (e.g., a gas flow bypass structure).

Here, “inner surface” may generally refer to the surface of an opening or aperture within the MCA structure. In at least one embodiment, the inner surface may converge from the top of the opening to the bottom of the opening, forming a cone.

Here, “wafer chuck assembly” may generally refer to a specialized structure included in a wafer processing apparatus, for mounting and supporting a wafer during processing. In at least one embodiment, a wafer chuck assembly may include a chuck and a pedestal supporting the chuck.

Here, “gas distribution showerhead” may generally refer to a specialized manifold for distributing process gases into a wafer processing apparatus (e.g., the vacuum chamber). In at least one embodiment, a gas distribution showerhead may distribute process gases for etching and deposition processes, such as PECVD.

Here, “rotary indexer’ may generally refer to a spindle apparatus within a process vacuum chamber operable to transfer wafers between different wafer chuck assemblies within the vacuum chamber. In at least one embodiment, a rotary indexer may comprise a wafer transfer paddle attached to one or more arms extending from a spindle.

Here, “indexing arms” may generally refer to robotic arms extending from a spindle of a rotary indexer. In at least one embodiment, the arms may have a wafer transfer paddle attached to a distal end.

Here, “process station” may generally refer to one or more dedicated regions of a vacuum chamber within a wafer processing apparatus operable to process wafers. In at least one embodiment, a process station includes a wafer chuck assembly and a showerhead.

Here, “load lock” may generally refer to a specialized chamber having a door or hatch enabling loading of wafers at atmospheric pressure into the load lock. A load lock may be physically connected to a vacuum chamber of a wafer processing apparatus. The load lock may house a robotic transfer arm that transfers wafers loaded into the load lock to the vacuum chamber after the load lock is pumped down to the vacuum level of the vacuum chamber.

Here, “lift pin” may generally refer to an elongated structure (e.g., a pin) that extends from a wafer chuck to lift a wafer off the surface of the wafer chuck or off a wafer transfer paddle.

Here, “neutral position” may generally refer to a position of an indexing arm that is a park position between process stations. In at least one embodiment, a neutral position may between wafer chuck assemblies.

Here, terms “substantially,” “close,” “approximately,” “near,” and “about,” generally refer to being within +/−10% of a target value. Unless otherwise specified in the explicit context of their use, the terms “substantially equal,” “about equal” and “approximately equal” mean that there is no more than incidental variation between two things so described. In the art, such variation is typically no more than +/−10% of the referred value.

To address the limitations described herein, a wafer transfer paddle comprising minimum contact area (MCA) features comprising process gas-diverting features is described. The gas-diverting features may mitigate deposition of process materials on the wafer contact surfaces of the MCA features. The reduction of material deposition on surfaces of the MCA features that may contact in-process wafers during transfer from station to station may reduce or eliminate undesirable marking.

In at least one embodiment, the gas-diverting features include annular-shaped MCA features comprising a through-hole aperture that extends through the MCA feature to open on the bottom side of the wafer transfer paddle. The through-hole apertures may permit passage of process gases through the MCA feature itself to mitigate deposition of solid materials on the contact surface of the MCA feature. In at least one embodiment, gas diverting features include openings in the wafer transfer paddle (e.g., slots, holes, notches) adjacent to the MCA to enhance the velocity of process gases to bypass the exterior walls of the MCA feature, suppressing deposition of solid material on the surfaces of the MCA feature.

For example, process gases may be pulled through a gas-diverting opening through and/or adjacent to an MCA feature. The process gas may flow within the gas-diverting feature above a critical velocity by vacuum-induced flow. The critical velocity of the process gas may be related to the mass transfer of impingement of precursors on reactive surfaces. The critical gas velocity may correspond to a maximum precursor mass transfer rate that is about the same as the surface reaction kinetic rate. By diverting process gases away from potentially reactive surfaces of the MCA features, mass transfer of precursor molecules to the MCA feature surface may be significantly reduced, causing a reduction in the rate of surface chemical reactions that may produce a deposited film, for example. Advantageously, undesirable marking of wafer backside layers or films may be mitigated or eliminated by the inclusion of gas-diverting features on or near the MCA features.

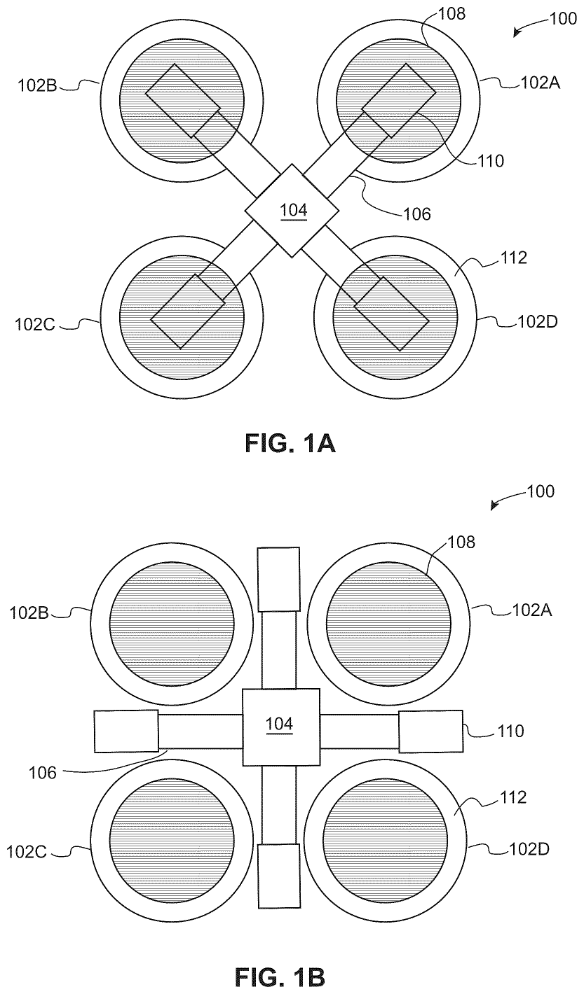

FIGS. 1A and 1B illustrate a plan view of wafer processing chamber 100 comprising four processing stations 102 and a four-arm rotary indexer 104, in accordance with at least one embodiment. In at least one embodiment, each arm 106 of rotary indexer 104 comprises a wafer transfer paddle (not shown) on its distal end. In FIG. 1A, wafers 108 are shown carried by each of the arms 106, each wafer 108 is supported by a wafer transfer paddle 110. In at least one embodiment, wafers 108 are shown with a transparent shading so as not to obscure features, such as wafer transfer paddles 110, below wafers 108. In at least one embodiment, wafer transfer paddles 110 may comprise MCA features (not shown) that directly contact wafers 108. In at least one embodiment, each wafer 108 is placed by rotary indexer 104 onto wafer chuck pedestals 112 at stations 102, labeled 102A, 102B, 102C and 102D. Not shown are process gas delivery systems, commonly known as shower heads, comprising one or more overhead nozzles to direct process gases over a wafer on a pedestal.

In at least one embodiment, stations 102 may each comprise a different process. For example, station 102A may comprise a first plasma-enhanced chemical vapor deposition (PECVD) process of a particular chemistry. In at least one embodiment, station 102B may comprise a second PECVD process running a different chemistry from the first process running at station 102A. In at least one embodiment, station 102C may run a process chemistry different from station 102D. In at least one embodiment, stations 102A, 102B, 102C, and 102D may run different processes chemistries. In at least one embodiment, rotary indexer 104 may transfer up to four wafers (e.g., wafers 108A, 108B, 108C, and 108D) between stations 102A, 102B, 102C, and 102D. In at least one embodiment, a wafer on station 102A may be transferred to any one of stations 102B, 102C and 102D. In at least one embodiment, multiple wafers may be similarly transferred between any of stations 102A-102D. For example, two wafers 108 at stations 102A and 102B may be transferred to stations 102C and 102D after a first PECVD process is complete.

In at least one embodiment, new (unprocessed) wafers 108 may be transferred into chamber 100 by a robot transfer arm (not shown) through load locks, placing them on pedestals 110 at station 102A and 102B. In at least one embodiment, wafers 108 transferred to stations 102C and 102D may receive a second PECVD layer, while wafers 108 at stations 102A and 102B receive the first PECVD layer. In at least one embodiment, when the depositions are terminated, rotary indexer 104 may be rotated 180 degrees, transferring wafers 108 from stations 102A and 102B to stations 102C and 102D. In at least one embodiment, the PECVD cycle may repeat, depositing first layers on new wafers 108 at stations 102A and 102B. In at least one embodiment, a second PECVD layer may be coated on wafers 108 at stations 102C and 102D. In at least one embodiment, wafers 108 at stations 102C and 102D, having both PECVD layers, may be transferred back to stations 102A and 102B. In at least one embodiment, the robot transfer arm may reenter chamber 100 and fetch the wafers from stations 102A and 102B, replacing them with two more unprocessed wafers. The sequence may then repeat for an entire batch of wafers, for example.

In FIG. 1B, arms 106 of rotary indexer 104 have been rotated about 45 degrees to park between stations 102. In at least one embodiment, this configuration may be assumed during the duration of the PECVD processes. In at least one embodiment, when wafers 108 are transferred to a station, lift pins on pedestals 112 may raise to lift wafers 108 off wafer transfer paddles 110 at the distal ends of arms 106. In at least one embodiment, rotary indexer 104 may rotate arms 106 about 45 degrees to clear pedestals 110. In at least one embodiment, lift pins may then lower, placing wafers 108 in close proximity or directly onto the surfaces of pedestals 110.

In at least one embodiment, during the deposition process, arms 106 of rotary indexer 104 and wafer transfer paddles 110 are in close proximity to stations 102. In at least one embodiment, wafer transfer paddles 110 may be exposed to process gases and plasmas that may deposit material on them. In at least one embodiment, after several deposition cycles, surfaces of wafer transfer paddles 110 may have a significant buildup of deposited material. In at least one embodiment, MCA features that contact backside surfaces of wafers 108 may transfer material from contact surfaces to wafer backsides. In at least one embodiment, this transfer of excess material on the MCA feature can result in undesirable marking of the wafer backside by particles of material adhering to the wafer. In instances where the front side of the wafer is to undergo further processing that may include photolithography, the marking may interfere with photomask alignment and planarity of the wafer. For example, particles adhering to the wafer backside may tilt the focal plane of the wafer in a mask aligner, causing some regions of the wafer to be out of focus during exposure.

In at least one embodiment, wafer backsides may also undergo processing. The particulate marking may interfere with etching and/or lithography of the wafer backside, for example. Particles may transfer to the wafer backside due to poor adhesion to the MCA feature. In at least one embodiment, MCA features may comprise materials, such as, but not limited to, oxide ceramics such as aluminum or titanium oxides (e.g., alumina, titania), that have high surface energies. Films comprising materials having low polarity may not adhere well to the high-surface energy materials. As a result, shear stress within the film on the MCA feature may break up the deposited film. The film may essentially tear apart, leaving pieces that may easily be lifted off of the MCA surface by the wafer.

In at least one embodiment, wafer transfer paddle embodiments comprising gas-diverting features associated with MCA features are described. In at least one embodiment, the gas-diverting features may mitigate buildup of deposition materials on the MCA features. In at least one embodiment, material transfer to wafer backsides may be reduced or eliminated when handled by wafer transfer paddles comprising gas-diverting features according to some embodiments.

In the following paragraphs describe the disclosed wafer transfer paddle and MCA feature embodiments.

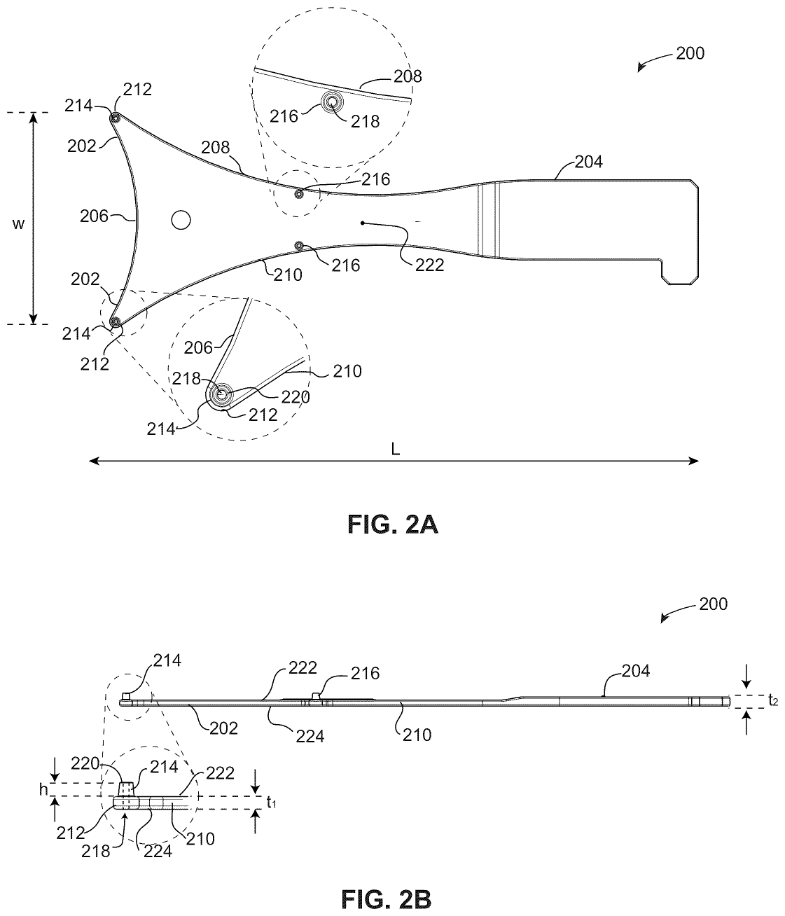

FIG. 2A illustrates a plan view of wafer transfer paddle 200 in accordance with at least one embodiment. The plan view shows the top surface features of wafer transfer paddle 200. In at least one embodiment, wafer transfer paddle 200 comprises forked prongs 202 extending from shank portion 204. In at least one embodiment, forked prongs 202 may be roughly triangular, comprising curved front edges 206 and curved side edges 208 and 210. In at least one embodiment, front edge 206 may join side edges 208 and 210 at apices 212. In at least one embodiment, MCA features 214 may be located at each of apices 212. In at least one embodiment, apices 202 may be rounded. In at least one embodiment, MCA features 216 may be located along curved edges 208 and 209. In at least one embodiment, MCA features 214 and 216 may be mesa-like structures and include aperture 218 as shown in the insets. In at least one embodiment, MCA features are substantially identical.

In at least one embodiment, wafer transfer paddle 200 may have overall dimensions of w width (at widest) and L length. In at least one embodiment, dimensions may be optimized to accommodate the size of the wafers handled. For example, for 300 mm wafer, width w may between 10 and 25 cm, and length L may be between 30 and 50 cm.

In at least one embodiment, MCA features 214 and 216 are annular structures, comprising aperture 218, opening at contact surface 220. In at least one embodiment, contact surface 220 is elevated above upper (e.g., top) surface 222 of wafer transfer paddle 200 by a z-height described below (see FIG. 2B). In at least one embodiment, the z-height is substantially the height of MCA feature 214 or 216 above surface 222. In at least one embodiment, contact surface 220 may form a rim about the opening of aperture 218. In at least one embodiment, aperture 218 extends through the z-height of MCA features 214 and 216, opening on the bottom side (not shown) of wafer transfer paddle 200. In at least one embodiment, aperture 218 is a gas-diverting feature. In at least one embodiment, aperture 218 may provide a path for flow of process gases through the MCA feature to substantially bypass contact surface 220 and sidewalls (described below). In at least one embodiment, MCA features 214 and 216 are proximal to front and side edges 206, 208 and 210. In at least one embodiment, MCA features 214 and 216 are substantially at edges 206, 208 and 210, as shown in the insets. In at least one embodiment, process gases may flow over edges 206, 208 and 210. In at least one embodiment, edges 206-210 may provide an additional flow bypass path for process gases to by bypass MCA features 214 and 216.

In at least one embodiment, wafer transfer paddles 200 may comprise high temperature ceramic materials such as, but not limited to, oxides of aluminum (e.g., alumina), titanium (e.g., titania) or tungsten. In at least one embodiment, other high-temperature ceramic materials may include, but are not limited to, silicon carbide and aluminum nitride. In at least one embodiment, MCA features 214 and 316 may comprise the same material as wafer transfer paddle 200.

FIG. 2B illustrates a profile view of wafer transfer paddle 200, in accordance with at least one embodiment. In at least one embodiment, wafer transfer paddle 200 comprises top surface 222, as noted above, and bottom surface 224. In the inset, hidden lines show aperture 218 extending the z-height h of MCA feature 214 and thickness t₁ of prong 202. In at least one embodiment, aperture 218 may extend vertically from contact surface 220 to bottom surface 224 of wafer transfer paddle 200. In at least one embodiment, wafer transfer paddle 200 has a thickness t₁ over a large portion of wafer transfer paddle 200 between top surface 222 and bottom surface 224. In at least one embodiment, shank portion 204 of wafer transfer paddle 200 has a thickness t₂ greater than t₁. In at least one embodiment, t₁ may be between a and b mm. In at least one embodiment, t₂ may be between c and d mm.

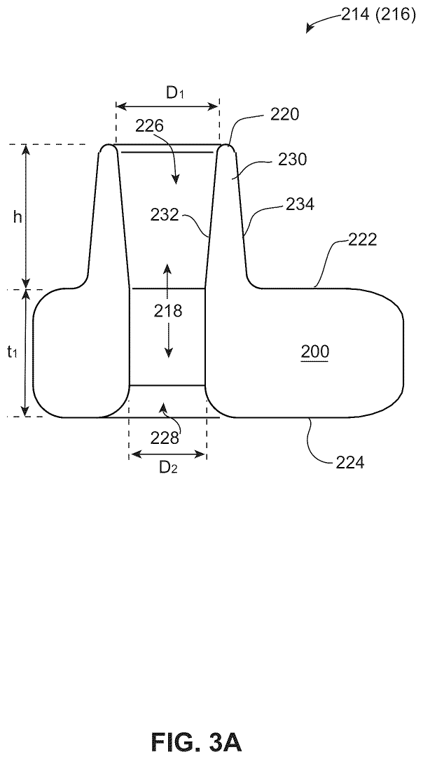

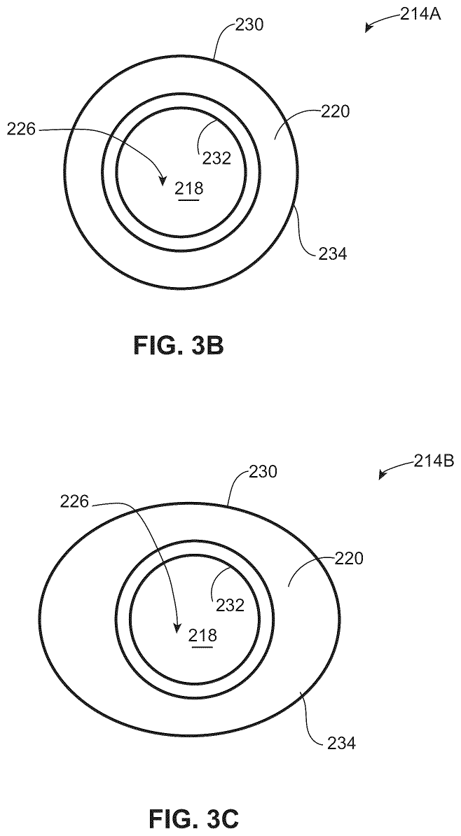

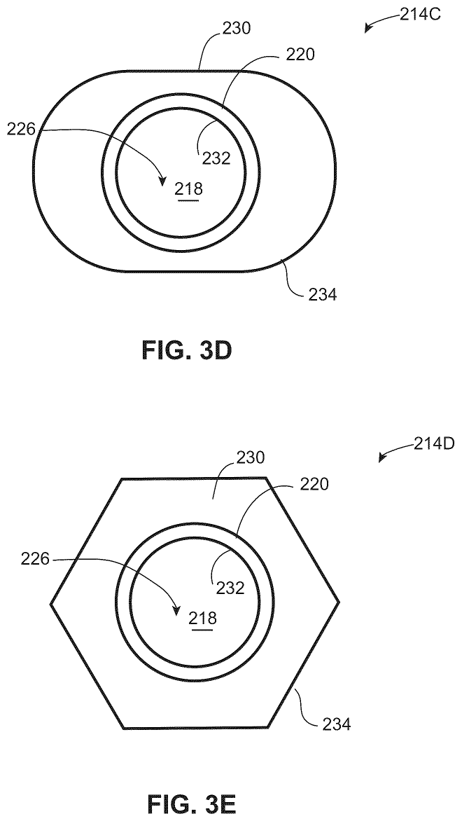

FIG. 3A illustrates a cross-sectional view of MCA features 214 or 216, in accordance with at least one embodiment. In at least one embodiment, MCA features 214 or 216 are identical. MCA features 214 (216) are substantially annular. In at least one embodiment, MCA features 214 and 216 have a circular horizontal cross section. In at least one embodiment, MCA features 214 and/or 216 have other horizontal cross-sectional shapes, as described below. In at least one embodiment, aperture 218 extends in the vertical (z-direction) through the z-height h of MCA features 214 and 216 and through thickness t₁ of wafer transfer paddle 200.

In at least one embodiment, aperture 218 comprises upper opening 226 through wafer contact surface 220. In at least one embodiment, wafer contact surface 220 forms a rim around opening 226. In at least one embodiment, wafer contact surface 220 may be convex as shown to encourage diversion of process gases past wafer contact surface 220. In at least one embodiment, the convex shape may also create a barrier for adhesion of deposited films on the convex surface. In at least one embodiment, at the same time, the contact to wafer is a circle, for example, having a larger contact area than a single point contact of a hemispherical convex surface.

In at least one embodiment, upper opening 226 has a diameter D₁. In at least one embodiment, diameter D₁ ranges between 0.5 and 3 mm. In at least one embodiment, aperture 218 comprises lower opening 228 in bottom surface 224 of wafer transfer paddle 200. In at least one embodiment, lower opening 228 may have a diameter D₂ that may be smaller than diameter D₁, according to some embodiments. In at least one embodiment, aperture 218 is surrounded by sidewall 230. In at least one embodiment, sidewall 230 is tapered, comprising diverging inner surface 232 and outer surface 234. In at least one embodiment, a portion of aperture 218 may be conical, as shown. In at least one embodiment, the conical shape may create a venturi, causing an increase of flow velocity of process gases passing through aperture 218 to enhance diversion of process gases from wafer contact surface 220.

FIGS. 3B-3E illustrate plan views of horizontal cross-sectional shape embodiments of MCA features 214 or 216 in accordance with at least one embodiment. In at least one embodiment, MCA features 214A have a substantially elliptical horizontal cross section, as shown in FIG. 3B. In at least one embodiment, MCA features 214B have a substantially circular horizontal cross section, as shown in FIG. 3C. In at least one embodiment, MCA features 214C may have a substantially oval horizontal cross section, as shown in FIG. 3D. In at least one embodiment, MCA features 214D may have a polygonal horizontal cross section, as shown in FIG. 3E.

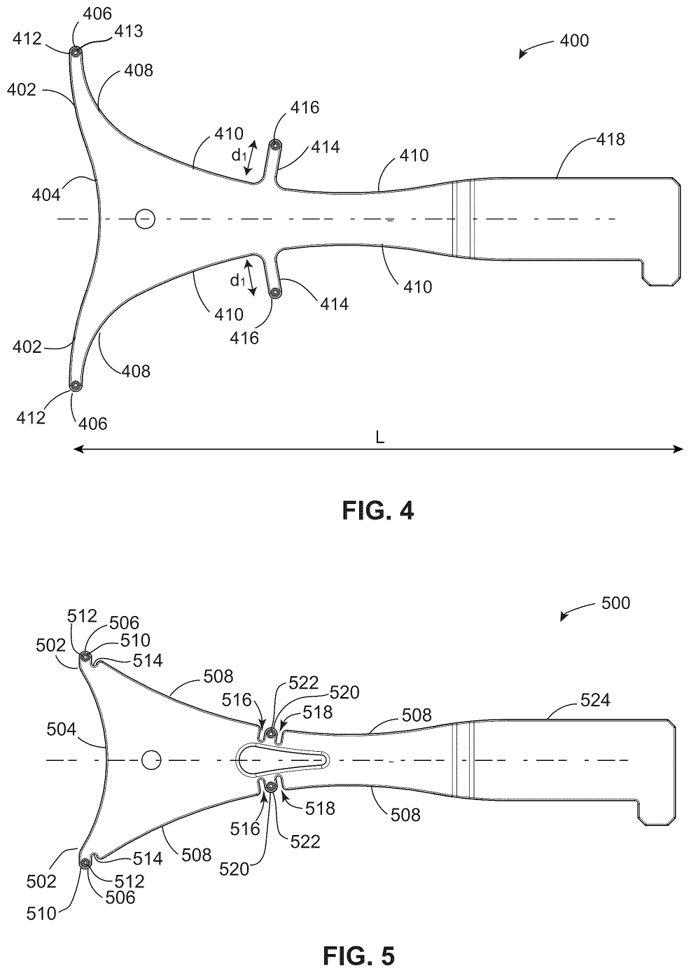

FIG. 4 illustrates a plan view of wafer transfer paddle 400 in accordance with at least one embodiment. In at least one embodiment, wafer transfer paddle 400 comprises features similar to wafer transfer paddle 200, described above. In at least one embodiment, wafer transfer paddle 400 may have a plane of symmetry, indicated by the dashed line, extending at least partially along length L. In at least one embodiment, described features having the same reference number on both sides of the plane of symmetry, for example frontal prongs 402, may be identical.

In at least one embodiment, wafer transfer paddle 400 comprises frontal prongs 402. In at least one embodiment, fontal prongs comprise a pronounced elongation. In at least one embodiment, front edge 404 has a concave curvature between frontal prongs 402. In at least one embodiment, front edge 404 may be swept rearward along frontal prongs 402, as shown. In at least one embodiment, apices 406 of frontal prongs 402 are rounded. In at least one embodiment, tear edges 408 extend opposite to front edge from apices 406. In at least one embodiment, rear edges 408 have a concave curvature and sweep rearward to blend with side edges 410. In at least one embodiment, side edges 410 may also have a slightly concave curvature, as shown. In at least one embodiment, MCA features 412 may be located at apices 406, as shown. In at least one embodiment MCA features 412 may be located at apices 406 to divert flow of process gases over outer surfaces of MCA features 412. In at least one embodiment, MCA features 412 comprise aperture 413. In at least one embodiment, aperture 413 is substantially similar to aperture 218, described above. Aperture 413 may be included aa a gas flow diversion feature of MCA feature 412, as described above.

In at least one embodiment, side prongs 414 may have a cantilevered peninsular structure, extending substantially orthogonally or obliquely from side edges 410. In at least one embodiment, side prongs 414 may extend a distance d₁ from side edges 410. In at least one embodiment, MCA features 416 may be located at the distal ends of side prongs 414. In at least one embodiment, MCA features 416 may be substantially identical to MCA features 412. MCA features 412 and 416 may be substantially identical to MCA features 214 and 216 shown in FIGS. 2A, 2B and 3A-3E. In at least one embodiment, the description pertaining to MCA features 214 and 216 may substantially pertain to MCA features 412 and 416.

In at least one embodiment, side prongs 414 are gas flow diversion features of wafer transfer paddle 400. are elongated a distance d₁ to encourage flow of process gases to bypass MCA features 416. Distance d₁ may be optimized to enable mechanical balance of a wafer handled by wafer transfer paddle 400, and to reduce resistance to flow external to MCA features 416.

In at least one embodiment, side edge 410 continues to extend rearward from side prongs 414 to shank portion 418. In at least one embodiment, side edges 410 may be substantially parallel along shank portion 418. In at least one embodiment, wafer transfer paddle 400 comprises a high temperature ceramic material as described above. Dimensions L and d1 may be adjusted to accommodate different wafer sizes.

FIG. 5 illustrates a plan view of wafer transfer paddle 500 in accordance with at least one embodiment. In at least one embodiment, wafer transfer paddle 500 comprises features similar to wafer transfer paddles 200 and 400, described above. In at least one embodiment, wafer transfer paddle 500 may have a plane of symmetry, indicated by the dashed line, extending at least partially along length L. Described features having the same reference number on both sides of the plane of symmetry, for example frontal prongs 502, may be identical in accordance with at least one embodiment.

In at least one embodiment, frontal prongs 502 may be defined by front edge 504 extending to apices 506. In at least one embodiment, front edge 504 may have a concave curvature. Side edges 508 may sweep rearward. In at least one embodiment, side edges 508 may also have a concave curvature. In at least one embodiment, MCA features 510 may be located at apices 506. In at least one embodiment, MCA features 510 may be substantially identical to MCA features described above. In at least one embodiment, MCA features may comprise aperture 512. In at least one embodiment, aperture 512 may be a gas flow diversion feature as described above.

In at least one embodiment, side edges 508 comprise notches 514 adjacent to MCA features 510. In at least one embodiment, notches 514 may extend inwardly from side edges 508 near apices 506, partially separating apices 506 from side edges 508. In at least one embodiment, apices 506 may be cantilevered, enabling MCA features 512 to be suspended with little lateral surfaced surrounding them. In at least one embodiment, notches 514 may be optimally dimensioned to enable adequate bypass flow of process gases from MCA features 512.

In at least one embodiment, side edges 508 may comprise notches 516 and 518, flanking cantilevered tongue 520. In at least one embodiment, MCA features 522 may be located at the tip of tongue 520. In at least one embodiment, notches 516 and 518 are gas flow diversion features. Notches 516 and 518 may be optimally dimensioned to enable diversion of gas flow around exterior surfaces of MCA features 522. MCA features 522 may be located at tip of tongue 520 to enable maximum diversion of process gases around the exterior surfaces of MCA features 522.

In at least one embodiment, side edges 508 may continue rearward to join shank portion 524. In at least one embodiment, side edges 508 may be substantially parallel along shank portion 524.

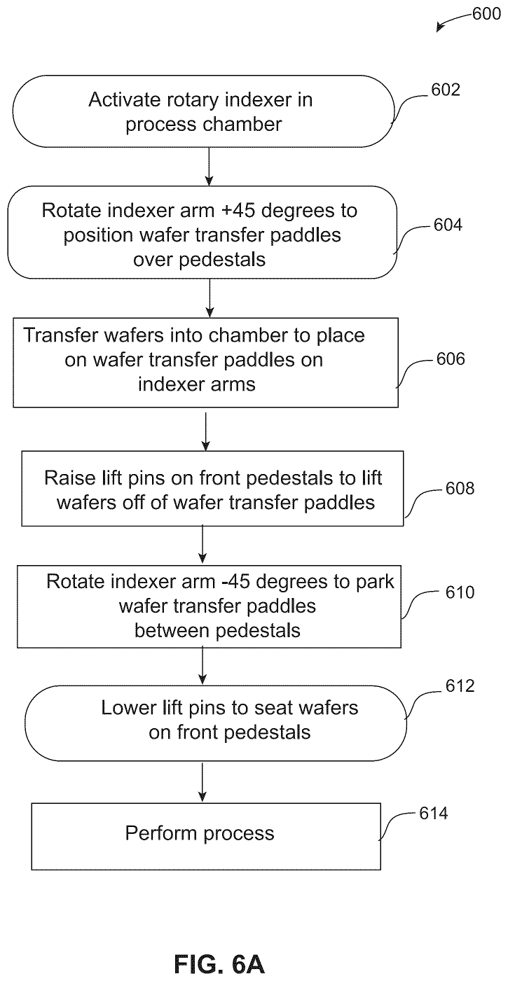

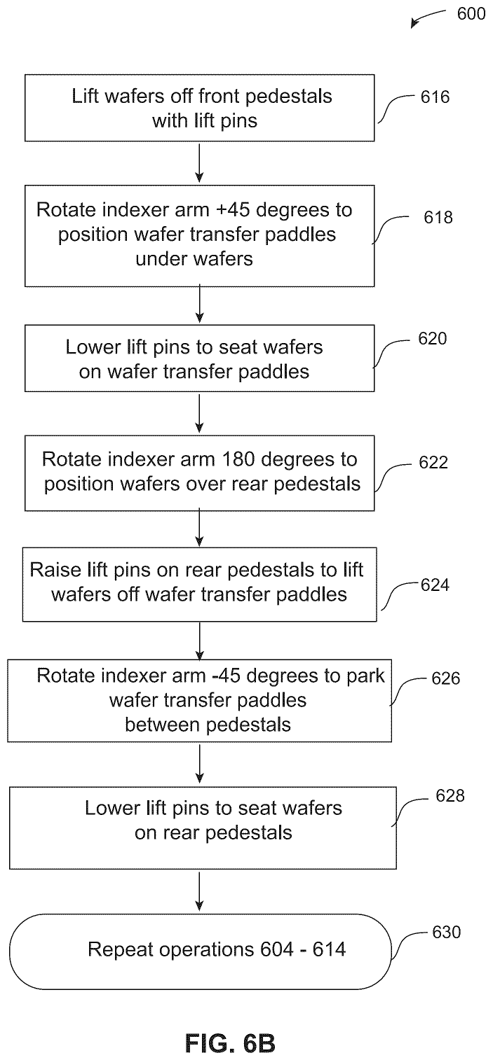

FIGS. 6A and 6B illustrate flow chart 600, summarizing an exemplary method for using a wafer transfer paddle in a deposition processing chamber, in accordance with at least one embodiment.

In at least one embodiment, the exemplary method may be carried out in a multi-station (e.g., a quad) PECVD processing chamber, similar to chamber 100 shown in FIGS. 1A and 1B. In at least one embodiment, the processing chamber may also be a multi-station physical deposition chamber or a multi-station etching chamber. In at least one embodiment, the processing chamber may be a four-station chamber comprising a rotary indexer. In at least one embodiment, the rotary indexer may comprise four arms, each arm equipped with a wafer transfer paddle according to embodiments described above (e.g., wafer transfer paddle 200, 400 and 500).

In at least one embodiment, the four process stations may be labeled A, B, C and D. In at least one embodiment, the centers of the process stations A, B, C and D may be arranged at the vertices of a square pattern, as shown in FIG. 1A, for example, with the rotary indexer at the center of the square. In at least one embodiment, the rotary indexer may be connected to a controller that is operable with a human-machine interface. In at least one embodiment, the rotary indexer may be initially positioned such that the indexer arms are parked between the four process stations. In at least one embodiment, the park position may be 45 degrees off of centers of process stations (e.g., as shown in FIG. 1B).

Referring now to FIG. 6A, the method begins with operation 602. At operation 602, in accordance with at least one embodiment, the rotary indexer is activated. At operation 604, the rotary indexer may be commanded to rotate+45 degrees to center the indexer arms and attached wafer transfer paddles over the pedestals of the process stations (e.g., as shown in FIG. 1A). It is understood that the direction of rotation may be indicated by the + or − sign in front of the rotational angle value. For example, the plus sign may indicate a clockwise rotation, whereas the minus sign may indicate a counterclockwise rotation. The directions of rotation employed in the following description are purely illustrative; and by no means indicative of a preferential direction.

In at least one embodiment, the process chamber may be equipped with one or more load locks and a robot transfer arm within the load locks. At operation 606, the robot transfer arm may transfer wafers into the chamber from load locks preloaded with wafers that are unprocessed or partially processed, in accordance with at least one embodiment. In at least one embodiment, the robotic arm may load the wafers onto the wafer transfer paddles positioned over the front process stations (e.g., stations A and B). In at least one embodiment, the wafers may be contacted by MCA features on the wafer transfer paddle. In at least one embodiment, the rotary indexer may be left in the park position, which may be a receiving position, and the robotic transfer arm may move a first wafer from a load lock that is in line with the foremost indexer arm. In at least one embodiment, the indexer may then be rotated +90 degrees to rotate a second arm to the receiving position. The robotic arm may transfer a second wafer from the load lock to the second wafer transfer paddle. The indexer may be rotated −45 degrees to reposition the wafers over stations A and B.

At operation 608, in accordance with at least one embodiment, lift pins on the front pedestals may be raised to lift wafers off the wafer transfer paddles. At operation 610, in accordance with at least one embodiment, while wafers are in the raised position, the rotary indexer may be rotated −45 degrees to replace indexer arms at the park position between the four process stations. At operation 612, in accordance with at least one embodiment, the lift pins may be lowered to seat the wafers on front pedestals at stations A and B.

At operation 614, in accordance with at least one embodiment, the deposition (or etch) process may be performed. In at least one embodiment, wafer at stations A and B may be coated with a first deposition layer.

Referring now to FIG. 6B, flow chart 600 continues to operation 616. In at least one embodiment, after completion of the process of operation 614, lift pins may again be raised to lift wafers off the pedestals at stations A and B. At operation 618, in accordance with at least one embodiment, the rotary indexer is rotated +45 degrees to position wafer transfer paddles under raised wafers at front stations A and B. At operation 620, in accordance with at least one embodiment, lift pins are lowered to seat wafers on wafer transfer paddles. In at least one embodiment, wafers may seat on MCA features described above. At operation 622, in accordance with at least one embodiment, the indexer arms are rotated 180 degrees to move wafers from front stations A and B to rear stations C and D, respectively. At operation 624, in accordance with at least one embodiment, lift pins on pedestals at stations C and D may be raised to lift wafers off the respective wafer transfer paddles. At operation 626, in accordance with at least one embodiment, the rotary indexer is commanded to rotate −45 degrees to clear process stations and park indexer arms between stations. At operation 628, in accordance with at least one embodiment, lift pins are lowered to seat wafers on rear pedestals at stations C and D.

At operation 630, in accordance with at least one embodiment, front stations may be reloaded with fresh wafers by repeating operations 604 to 612. After all stations are loaded, the deposition process may be repeated. In at least one embodiment, wafers at stations C and D may receive a second layer over the first, for example, while wafers at stations A and B may receive the first deposition layer.

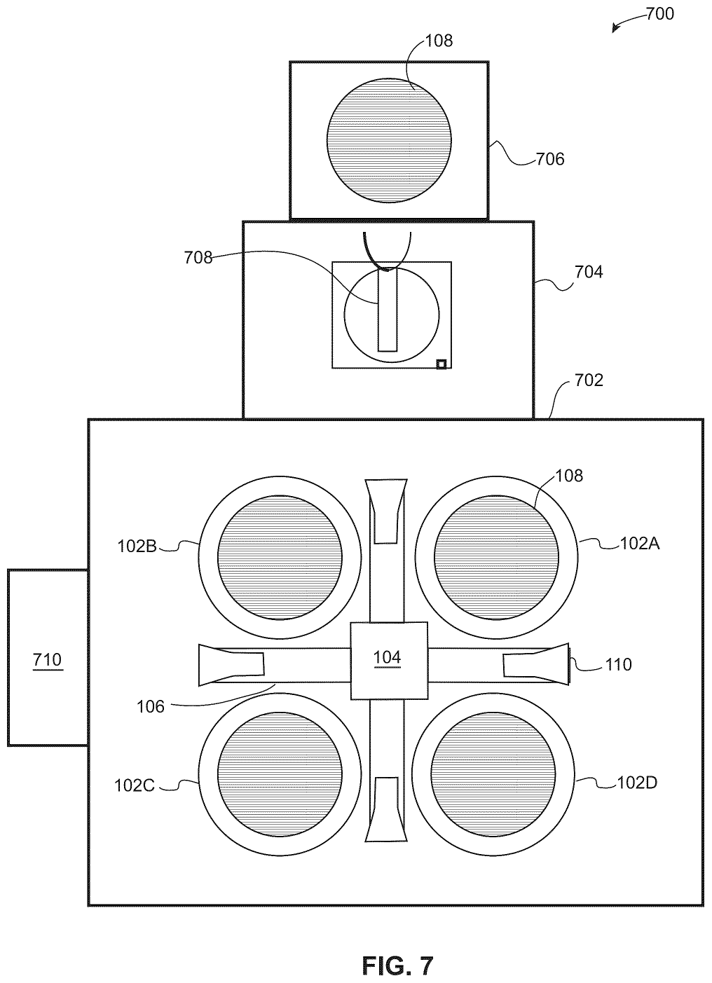

FIG. 7 illustrates a schematic profile view of wafer processing system 700. In at least one embodiment, wafer processing system 700 comprises processing chamber 702. In at least one embodiment, wafer transfer chamber 704 may be an antechamber at an entrance port to processing chamber 702. In at least one embodiment, load lock 706 may be coupled to wafer transfer chamber 704. In at least one embodiment, robotic transfer arm 708 may be within wafer transfer chamber 704. In at least one embodiment, load lock 706 may be preloaded with wafer(s) 108.

In at least one embodiment, processing chamber 702 may be a high-vacuum quad station PECVD chamber. In at least one embodiment, processing chamber may be a physical deposition chamber or an etch chamber. In at least one embodiment, processing chamber 702 comprises four processing stations 102A, 102B, 102C, and 102D. In at least one embodiment, stations 102 may each comprise a wafer pedestal comprising clamping mechanism, lift pins and heating elements (not shown). In at least one embodiment, stations 102 may be configured such that the centers of wafer pedestals are at the vertices of a square. In at least one embodiment, a showerhead (not shown) may be located above stations 102A-102D. In at least one embodiment, the showerheads may comprise a plurality of nozzles directed at the pedestals. In at least one embodiment, the showerheads may direct process gases or plasmas to wafer substrates seated on the pedestals. In at least one embodiment, rotary indexer 104 may be located at the center of the square array of processing stations 102A-102D. In at least one embodiment, rotary indexer 104 comprises four arms 106. Wafer transfer paddles 110 may be attached at the distal end of each arm 106. In at least one embodiment, wafer transfer paddles may be any one of wafer transfer paddles according to embodiments 200, 400 and 500 described above.

In at least one embodiment, the basic operation of processing chamber 700 has been described above and summarized by exemplary flow chart 600. In at least one embodiment, controller 710 may comprise a human-machine interface for programming and manual control of the process.

Following examples are provided that illustrate the various embodiments. The examples can be combined with other examples. As such, various embodiments can be combined with other embodiments without changing the scope of the invention.

Example 1 is a wafer processing tool, comprising a vacuum chamber comprising a wafer transfer arm, and a wafer transfer paddle comprising at least one minimum contact area (MCA) feature integral with an upper surface of the wafer transfer paddle and extending a z-height over the upper surface of the wafer transfer paddle, wherein the wafer transfer paddle comprises a gas flow bypass structure on or adjacent to the MCA feature.

Example 2 includes all features of example 1, wherein the MCA feature is adjacent to an edge of the wafer transfer paddle, wherein the gas flow bypass structure comprises a notch recessed inwardly from the edge, and wherein the notch is adjacent to the MCA feature.

Example 3 includes all features of example 2, wherein the notch comprises a curved edge between two straight edges.

Example 4 includes all features of example 1, wherein the gas flow bypass structure comprises a peninsular structure extending from a sidewall of the wafer transfer paddle, wherein the MCA feature is on a distal end of the peninsular structure.

Example 5 includes all features of example 1, wherein the gas flow bypass structure is an opening extending through the z-height of the MCA feature and through a lower surface of the wafer transfer paddle.

Example 6 includes all features of example 5, wherein the MCA feature has an annular form comprising a sidewall surrounding the opening.

Example 7 includes all features of example 6, wherein the annular form has a substantially circular cross section.

Example 8 includes all features of example 6, wherein the annular form has a substantially ellipsoid cross section.

Example 9 includes all features of example 6, wherein the annular form has a substantially oval cross section.

Example 10 includes all features of example 6, wherein the annular form has a substantially polygonal cross section.

Example 11 includes all features of example 5, wherein the MCA feature comprises a wafer contact surface between an outer surface of a sidewall of the MCA feature and a rim of the opening, wherein the wafer contact surface is substantially convex.

Example 12 includes all features of example 11, wherein the sidewall of the MCA feature comprises an inner surface around the opening and extending the z-height of the MCA feature, wherein the inner surface converges inwardly in such a way that the opening is conical at least along a portion of the inner surface.

Example 13 is a wafer processing system, comprising at least one wafer processing chamber comprising one or more wafer chuck assemblies, a gas distribution head above the one or more wafer chuck assemblies and a rotary indexer adjacent to the one or more wafer chuck assemblies, the rotary indexer comprising at least one indexing arm, coupled to a wafer handling paddle, the wafer transfer paddle comprising at least one minimum contact area (MCA) mesa integral with an upper surface of the wafer transfer paddle and extending a z-height over the upper surface of the wafer transfer paddle, wherein the wafer transfer paddle comprises a gas flow bypass structure on or adjacent to the MCA feature.

Example 14 includes all features of example 13, wherein the wafer handling system comprises a rotary indexer, the rotary indexer comprising one or more arms coupled to the wafer transfer paddle.

Example 15 is a method for operating a wafer processing system, comprising transferring one or more wafers into a wafer processing chamber comprising a rotary indexer comprising one or more indexing arms coupled to a wafer transfer paddle, the wafer transfer paddle comprising at least one minimum contact area (MCA) mesa integral with an upper surface of the wafer transfer paddle and extending a z-height over the upper surface of the wafer transfer paddle, wherein the wafer transfer paddle comprises a gas flow bypass structure on or adjacent to the MCA feature, rotating the at least one indexing arm to load the one or more wafers onto one or more processing stations within the processing chamber; and parking the at least one indexing arm to a neutral position,

Example 16 includes all the features of example 15, wherein transferring one or more wafers into the wafer processing chamber comprise transferring the one or more wafers from a load lock coupled to the wafer processing chamber with a robotic transfer arm.

Example 17 includes all the features of example 16, wherein transferring one or more wafers into the wafer processing chamber comprises placing the one or more wafers onto the wafer transfer paddles on the one or more indexing arms by the robotic transfer arm.

Example 18 includes all features of example 15, wherein rotating the at least one indexing arm to load the one or more wafers onto one or more processing stations within the processing chamber comprises raising lift pins to lift the one or more wafers off the wafer transfer paddle.

Example 19 includes all features of example 15, wherein parking the at least one indexing arm to a neutral position comprises rotating the at least one indexing arm to the side of the or more processing stations within the processing chamber.

Example 20 includes all features of example 19, wherein parking the at least one indexing arm to a neutral position comprises diverting gas flow over or through the at least one MCA feature.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1. A wafer processing tool, comprising:
a vacuum chamber comprising a wafer transfer arm; and
a wafer transfer paddle coupled to the wafer transfer arm, the wafer transfer paddle comprising a minimum contact area (MCA) feature integral with an upper surface of the wafer transfer paddle and extending a z-height over the upper surface of the wafer transfer paddle, wherein the wafer transfer paddle comprises a gas flow bypass structure on or adjacent to the MCA feature.

2. The wafer processing tool of claim 1, wherein the MCA feature is adjacent to an edge of the wafer transfer paddle, wherein the gas flow bypass structure comprises a notch recessed inwardly from the edge, and wherein the notch is adjacent to the MCA feature.

3. The wafer processing tool of claim 2, wherein the notch comprises a curved edge between two straight edges.

4. The wafer processing tool of claim 1, wherein the gas flow bypass structure comprises a peninsular structure extending from a sidewall of the wafer transfer paddle, wherein the MCA feature is on a distal end of the peninsular structure.

5. The wafer processing tool of claim 1, wherein the gas flow bypass structure is an opening extending through the z-height of the MCA feature and through a lower surface of the wafer transfer paddle.

6. The wafer processing tool of claim 5, wherein the MCA feature has an annular form comprising a sidewall surrounding the opening.

7. The wafer processing tool of claim 6, wherein the annular form has a substantially circular cross section.

8. The wafer processing tool of claim 6, wherein the annular form has a substantially ellipsoid cross section.

9. The wafer processing tool of claim 6, wherein the annular form has a substantially oval cross section.

10. The wafer processing tool of claim 6, wherein the annular form has a substantially polygonal cross section.

11. The wafer processing tool of claim 5, wherein the MCA feature comprises a wafer contact surface between a sidewall of the MCA feature and a rim of the opening, and wherein the wafer contact surface is substantially convex.

12. The wafer processing tool of claim 11, wherein the sidewall of the MCA feature comprises an inner surface around the opening and extending the z-height of the MCA feature, and wherein the inner surface converges inwardly in such a way that the opening is conical at least along a portion of the inner surface.

13. A wafer processing system, comprising:
at least one wafer processing chamber comprising one or more wafer chuck assemblies;
a gas distribution showerhead above the one or more wafer chuck assemblies; and
a rotary indexer adjacent to the one or more wafer chuck assemblies, the rotary indexer comprising at least one indexing arm, coupled to a wafer handling paddle, the wafer handling paddle comprising at least one minimum contact area (MCA) feature integral with an upper surface of the wafer handling paddle and extending a z-height over the upper surface of the wafer handling paddle.

14. The wafer processing system of claim 13, wherein the wafer handling paddle comprises a gas flow bypass structure on or adjacent to the MCA feature.

15. A method for operating a wafer processing system, comprising:
transferring one or more wafers into a wafer processing apparatus comprising a rotary indexer comprising at least one indexing arm coupled to a wafer transfer paddle, the wafer transfer paddle comprising a minimum contact area (MCA) feature integral with an upper surface of the wafer transfer paddle and extending a z-height over the upper surface of the wafer transfer paddle; and
rotating the at least one indexing arm to load the one or more wafers onto one or more processing stations within the wafer processing apparatus; and
parking the at least one indexing arm in a neutral position.

16. The method of claim 15, wherein transferring the one or more wafers into the wafer processing apparatus comprise transferring the one or more wafers from a load lock coupled to the wafer processing apparatus with a robotic transfer arm.

17. The method of claim 16, wherein transferring the one or more wafers into the wafer processing apparatus comprises placing the one or more wafers onto the wafer transfer paddle on the at least one indexing arm by the robotic transfer arm.

18. The method or claim 15, wherein rotating the at least one indexing arm to load the one or more wafers onto the one or more processing stations within the wafer processing apparatus comprises raising one or more lift pins to lift the one or more wafers off the wafer transfer paddle.

19. The method of claim 15, wherein parking the at least one indexing arm in the neutral position comprises rotating the at least one indexing arm to a side of the one or more processing stations within the wafer processing apparatus.

20. The method of claim 19, wherein parking the at least one indexing arm in the neutral position comprises diverting gas flow over or through the MCA feature.
